(19) United States
(12) Patent Application Publication
(10) Pub. No.: US 2022/0266710 A1
(43) Pub. Date: Aug. 25, 2022

(54) SYSTEM AND METHOD FOR DIAGNOSING CHARGER FOR FUEL CELL VEHICLE

(71) Applicant: HYUNDAI KEFICO CORPORATION, Gunpo (KR)

(72) Inventors: Sung-Ho Kim, Hanam (KR); Ji-Hye Park, Hanam (KR)

(21) Appl. No.: 17/673,228

(22) Filed: Feb. 16, 2022

(30) Foreign Application Priority Data
Feb. 22, 2021 (KR) 10-2021-0023187

(51) Int. Cl. B60L 53/60; B60L 53/18; B60L 58/30; H01M 8/04313

(52) U.S. Cl. CPC B60L 53/60; B60L 53/18; B60L 58/30; H01M 8/04313

(57) ABSTRACT

A system for diagnosing a charger for a fuel cell vehicle includes a charge cable connector including a first pin for power supply and a second pin for communication control and configured to be connected to a charger of a fuel charging station, a detection unit configured to detect a voltage value based on whether the charge cable connector is connected to the charger, a microcomputer configured to output a control signal for communication control over the charger and diagnose whether at least one of the charge cable connector or an infrared ray (IR) communication unit of the charger has failed, based on the detected voltage value, and a switch configured to be turned on or off in response to the control signal.

### CROSS-REFERENCE TO RELATED APPLICATION

This application claims under 35 U.S.C. § 119(a) the benefit of Korean Patent Application No. 10-2021-0023187, filed on Feb. 22, 2021, the entire contents of which are incorporated by reference herein.

### BACKGROUND

### (a) Technical Field

Exemplary embodiments of the present disclosure relate to a system and method for diagnosing a charger for a fuel cell vehicle, more particularly, to the system and method that can diagnose failure of a charge cable connector and an infrared ray (IR) communication unit of the charger, which may occur during actual charging as well as prior to fuel charging of the fuel cell vehicle.

### (b) Description of the Related Art

In general, a fuel cell vehicle is a vehicle that utilizes a fuel cell stack as a main power source of the vehicle, and travels by driving an electric motor with electric energy generated from the fuel cell stack. The fuel cell stack generates electric energy through an electrochemical reaction between hydrogen, that is, a fuel gas supplied by a hydrogen supply apparatus including a hydrogen tank, and oxygen in the air, that is, an oxidizer gas supplied by an air supply apparatus including a blower or a compressor.

In a fuel cell vehicle, it is important to safely and compactly store hydrogen that is fuel. Various hydrogen storage techniques satisfying both range and vehicle safety requirements have been developed.

Hydrogen is commonly stored in a hydrogen tank that is light weight and high strength and can also withstand high pressures. In order to secure a boarding space and sufficient range (mileage), a hydrogen tank capable of storing hydrogen under high pressure, such as a 350 bar or 700 bar specification, is widely used.

Since the fuel cell vehicle uses hydrogen as fuel as described above, a hydrogen storage system for storing hydrogen needs to be essentially mounted on the fuel cell vehicle. A high pressure hydrogen storage system having the highest 700 bar specification (at current commercialization levels worldwide) may be mounted on the fuel cell vehicle.

The fuel cell vehicle periodically is filled with hydrogen at a charging station. In this case, hydrogen is pressurized in a high pressure state, and the hydrogen tank of the vehicle is charged with the hydrogen. In a hydrogen storage system having high pressure of 700 bar, upon charging, hydrogen pressure rises up to a maximum of 875 bar, and a temperature thereof is permitted up to a maximum of 85° C.

Furthermore, in order to secure safety upon hydrogen charging, a hydrogen charging speed needs to be controlled. To this end, in a key-off state, communication is performed between the charging station and the vehicle during hydrogen fuel charging. Data such as pressure and a temperature within the hydrogen storage system, which are measured in the vehicle through the communication, is provided to the charging station. In this case, wired or wireless communication may be performed between the charging station and the vehicle, but IR communication regulated in SAE J2799, that is, a wireless communication protocol, may be applied.

The fuel cell vehicle is connected to a charger of the charging station for hydrogen fuel charging. The fuel cell vehicle and the charger transmit and receive hydrogen fuel quantities and charging information through IR communication. In this case, a failure may occur in the IR communication unit of the charger. When a failure occurs in the IR communication unit, there is a problem in that the fuel cell vehicle does not properly measure a hydrogen fuel quantity or fuel is not stored in a desired quantity.

Accordingly, there is a need to develop technology capable of diagnosing failure of an IR communication unit of a charger in a fuel cell vehicle.

### SUMMARY

Various embodiments of the present disclosure are directed to providing a system and method for diagnosing a charger for a fuel cell vehicle, which can diagnose failure of a charge cable connector and an infrared ray (IR) communication unit of the charger, which may occur during actual charging as well as prior to fuel charging of the fuel cell vehicle.

Objects to be solved by the present disclosure are not limited to the aforementioned object, and the other objects not described above may be evidently understood from the following description by those skilled in the art.

In an embodiment, a system for diagnosing a charger for a fuel cell vehicle may include a charge cable connector including a first pin for power supply and a second pin for communication control and configured to be connected to the charger of a fuel charging station, a detection unit configured to detect a voltage value based on whether the charge cable connector is connected to the charger, a microcomputer configured to output a control signal for communication control over the charger and diagnose whether at least one of the charge cable connector or an infrared ray (IR) communication unit of the charger has failed, based on the detected voltage value, and a switch configured to be turned on or off in response to the control signal.

In an embodiment, the detection unit may include a first resistor having one side connected in series to a power source, a second resistor having one side connected in series to a ground, and a third resistor having one side connected in series to the second pin. At least one of the first resistor, the second resistor, or the third resistor may form a voltage distribution circuit.

In an embodiment, the detection unit may further include a Zener diode having one side connected in parallel to the microcomputer and the other side connected to the ground, and configured to protect the microcomputer upon battery open in at least one of the first pin or the second pin.

In an embodiment, the microcomputer may diagnose whether at least one of the charge cable connector or the IR communication unit has failed when fuel charging for the fuel cell vehicle is necessary, and may determine that fuel charging is possible when the charge cable connector and the IR communication unit are normal.

In an embodiment, when a voltage value of a power source is not detected before the charge cable connector is connected to the charger, the microcomputer may diagnose the first pin as short. When the voltage value of the power source is detected, the microcomputer may turn off the switch by transmitting a low control signal to the switch, may compare a voltage value, detected by the detection unit, with a reference voltage value stored in a lookup table, and may diagnose the second pin as at least one of normal, battery short or ground short based on a result of the comparison.

In an embodiment, when the first pin and second pin of the charge cable connector are normal and the charge cable connector is connected to the charger, the microcomputer may turn off the switch by transmitting a low control signal to the switch, may compare a voltage value, detected by the detection unit, with a reference voltage value stored in the lookup table, and may diagnose the IR communication unit as at least one of normal, short, or open based on a result of the comparison.

In an embodiment, the microcomputer may diagnose whether the IR communication unit has failed upon fuel charging for the fuel cell vehicle.

In an embodiment, upon fuel charging for the fuel cell vehicle, the microcomputer may turn off or on the switch by transmitting a low control signal or a high control signal to the switch, may compare a voltage value, detected by the detection unit, with a reference voltage value stored in a lookup table, and may diagnose the IR communication unit as at least one of normal, short, or open based on a result of the comparison.

In an embodiment, a method of diagnosing a charger for a fuel cell vehicle may include diagnosing, by a microcomputer, whether at least one of a charge cable connector or an infrared ray (IR) communication unit of a charger has failed when fuel charging for a fuel cell vehicle is necessary, determining, by the microcomputer, that fuel charging for the fuel cell vehicle is possible when both the charge cable connector and the IR communication unit are normal, and diagnosing, by the microcomputer, whether the IR communication unit has failed upon fuel charging for the fuel cell vehicle.

In an embodiment, in diagnosing whether the at least one of the charge cable connector or the IR communication unit of the charger has failed, when a voltage value of a power source is not detected before the charge cable connector is connected to the charger, the microcomputer may diagnose the first pin of the charge cable connector as short. When the voltage value of the power source is detected, the microcomputer may turn off the switch by transmitting a low control signal to the switch, may compare a voltage value, detected by a detection unit, with a reference voltage value stored in a lookup table, and may diagnose the second pin of the charge cable connector as at least one of normal, battery short or ground short based on a result of the comparison.

In an embodiment, in diagnosing whether the at least one of the charge cable connector or the IR communication unit of the charger has failed, when the first pin and second pin are normal and the charge cable connector is connected to the charger, the microcomputer may turn off the switch by transmitting a low control signal to the switch, may compare a voltage value, detected by the detection unit, with a reference voltage value stored in the lookup table, and may diagnose the IR communication unit as at least one of normal, short, or open based on a result of the comparison.

In an embodiment, in diagnosing whether the IR communication unit has failed, the microcomputer may turn off or on the switch by transmitting a low control signal or a high control signal to the switch, may compare a voltage value, detected by a detection unit, with a reference voltage value stored in a lookup table, and may diagnose the IR communication unit as at least one of normal, short, or open based on a result of the comparison.

The system and method for diagnosing a charger for a fuel cell vehicle according to embodiments of the present disclosure can secure the safety of a driver of a fuel cell vehicle by diagnosing the failure of the charge cable connector and the IR communication unit of the charger, which may occur during actual charging as well as prior to fuel charging for the fuel cell vehicle.

The system and method for diagnosing a charger for a fuel cell vehicle according to embodiments of the present disclosure can diagnose whether the IR communication unit and the charge cable connector have failed, by using a total of two pins of the first pin for power supply and the second pin for communication control, without additionally allocating a separate connector pin in order to diagnose whether the IR communication unit and the charge cable connector have failed.

The system and method for diagnosing a charger for a fuel cell vehicle according to embodiments of the present disclosure can secure the safety of a driver by determining whether the IR communication unit of the charger has failed prior to the start of hydrogen fuel charging and during hydrogen fuel charging.

Effects of the present disclosure are not limited to the aforementioned effects, and may include various effects within a range evident to those skilled in the art from the contents to be described hereinafter.

### BRIEF DESCRIPTION OF THE DRAWINGS

FIGS. 1 and 2 are diagrams for describing a system for diagnosing a charger for a fuel cell vehicle according to an embodiment of the present disclosure.

FIG. 3 is a circuit diagram for describing the system for diagnosing a charger for a fuel cell vehicle according to an embodiment of the present disclosure.

FIGS. 4A to 4C are exemplary diagrams for describing a method of diagnosing a failure of the IR communication unit of a charger according to an embodiment of the present disclosure.

FIG. 5 is a flowchart for describing a method of diagnosing a charger of a fuel cell vehicle according to an embodiment of the present disclosure.

FIG. 6 is a flowchart for describing a method of determining whether hydrogen fuel charging for a fuel cell vehicle may be performed according to an embodiment of the present disclosure.

FIG. 7 is a flowchart for describing a method of diagnosing whether the IR communication unit has failed during fuel charging for a vehicle according to an embodiment of the present disclosure.

### DETAILED DESCRIPTION OF THE ILLUSTRATED EMBODIMENTS

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

As is traditional in the corresponding field, some exemplary embodiments may be illustrated in the drawings in terms of functional blocks, units, and/or modules. Those of ordinary skill in the art will appreciate that these block, units, and/or modules are physically implemented by electronic (or optical) circuits such as logic circuits, discrete components, processors, hard-wired circuits, memory elements, wiring connections, and the like. When the blocks, units, and/or modules are implemented by processors or similar hardware, they may be programmed and controlled using software (e.g., code) to perform various functions discussed herein. Alternatively, each block, unit, and/or module may be implemented by dedicated hardware or as a combination of dedicated hardware to perform some functions and a processor (e.g., one or more programmed processors and associated circuitry) to perform other functions. Each block, unit, and/or module of some exemplary embodiments may be physically separated into two or more interacting and discrete blocks, units, and/or modules without departing from the scope of the inventive concept. Further, blocks, units, and/or module of some exemplary embodiments may be physically combined into more complex blocks, units, and/or modules without departing from the scope of the inventive concept.

Hereinafter, a system and method for diagnosing a charger for a fuel cell vehicle will be described with reference to the accompanying drawings through various exemplary embodiments. In such a process, the thicknesses of lines or the sizes of elements illustrated in the drawings may have been exaggerated for the clarity of a description and for convenience' sake. Furthermore, terms to be described hereinafter may be defined by taking into consideration functions in the present disclosure, and may be different depending on a user, an operator's intention or practice. Accordingly, each term should be defined based on contents over the entire specification.

An implementation described in this specification may be realized as a method or process, apparatus, software program, data stream or signal, for example. Although the present disclosure has been discussed only in the context of a single form of an implementation (e.g., discussed as only a method), an implementation having a discussed characteristic may also be realized in another form (e.g., apparatus or program). The apparatus may be implemented as proper hardware, software or firmware. The method may be implemented in an apparatus, such as a processor commonly referring to a processing device, including a computer, a microprocessor, an integrated circuit or a programmable logic device, for example. The processor includes a communication device, such as a computer, a cell phone, a mobile phone/personal digital assistant (“PDA”) and another device which facilitates the communication of information between end-users.

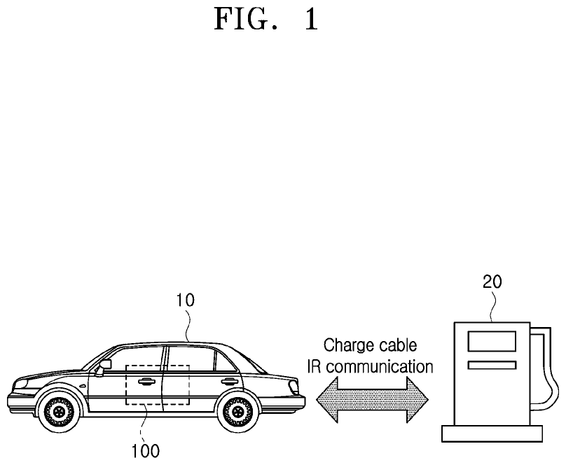

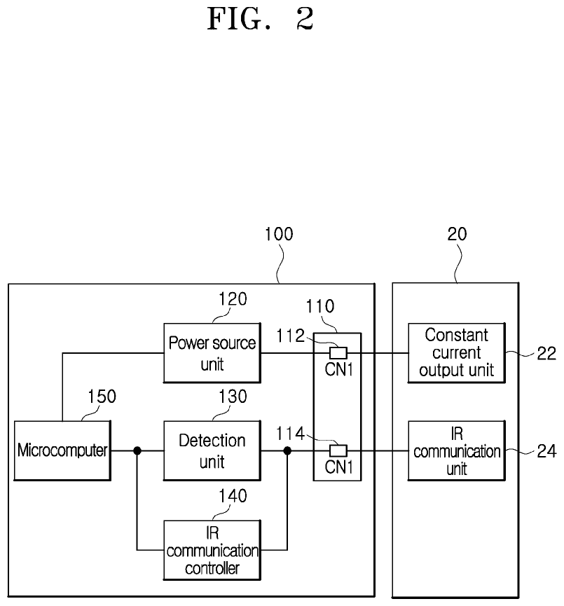

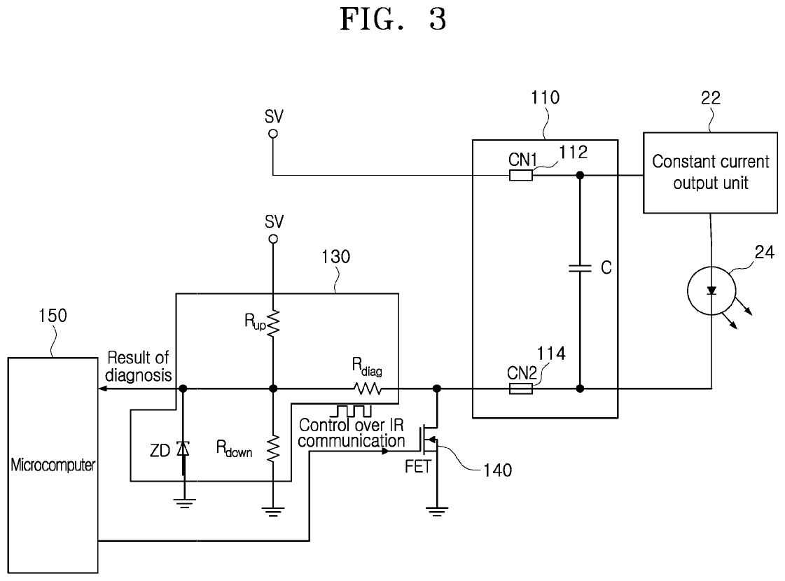

FIGS. 1 and 2 are diagrams for describing a system for diagnosing a charger for a fuel cell vehicle according to an embodiment of the present disclosure. FIG. 3 is a circuit diagram for describing the system for diagnosing a charger for a fuel cell vehicle according to an embodiment of the present disclosure.

Referring to FIGS. 1 to 3, the system for diagnosing a charger of a fuel cell vehicle 10 according to an embodiment of the present disclosure may include a fuel cell charging control apparatus 100 provided in the fuel cell vehicle 10 and a charger 20 provided in a fuel cell charging station.

The fuel cell vehicle 10 is connected to the charger 20 for hydrogen fuel charging. The fuel cell vehicle 10 and the charger 20 may transmit and receive hydrogen fuel quantities and charging information through IR communication. Infrared ray (IR) communication between the vehicle 10 and the charger 20 during hydrogen charging for the fuel cell vehicle 10 is performed for the purpose of data communication for transmitting and receiving data necessary for hydrogen charging control over the vehicle 10.

The charger 20 may include a constant current output unit 22 and an infrared ray communication unit 24 (hereinafter referred to as an “IR communication unit”).

The constant current output unit 22 may be a current output source for stably driving a diode for IR communication within the charger 20.

The fuel cell charging control apparatus 100 may diagnose whether a charge cable connector 110 connected to the charger 20 has failed and whether the IR communication unit 24 within the charger 20 has failed.

The fuel cell charging control apparatus 100 may include the charge cable connector 110, a power source unit 120, a detection unit 130, an IR communication controller 140, and a microcomputer 150.

The charge cable connector 110 may include a first pin (CN1) 112 for power supply and a second pin (CN2) 114 for communication control, and may be connected to the charger 20 of a fuel charging station. In this case, the first pin 112 may be a power supply pin for communication with the charger 20 of a hydrogen fuel charging station. The second pin 114 may be a communication control pin for communication with the charger 20 of the hydrogen fuel charging station.

The charge cable connector 110 may include a capacitor C between the first pin 112 and the second pin 114. In this case, the capacitor may be provided for electrostatic protection and communication stabilization attributable to the attachment and detachment of the charge cable connector 110 and another factor.

The power source unit 120 may supply an internal power source of the fuel cell charging control apparatus 100, and may be charged through the charge cable connector 110. In this case, the internal power source may be a pull-up source for the power source and diagnosis of the constant current output unit 22 within the charger 20.

The detection unit 130 may be connected to the charge cable connector 110, and may detect a voltage value based on whether the charge cable connector 110 is connected to the charger 20.

The detection unit 130 may include a first resistor having one side connected in series to a power source, a second resistor having one side connected in series to the ground, and a third resistor having one side connected in series to the second pin 114. At least one of the first resistor, the second resistor, or the third resistor may form a voltage distribution circuit.

Furthermore, the detection unit 130 may further include a Zener diode ZD having one side connected in parallel to the microcomputer 150 and the other side connected to the ground, and configured to protect the microcomputer 150 upon battery open in at least one of the first pin 112 or the second pin 114.

The IR communication controller 140 may be an element for delivering IR communication information by controlling the IR communication unit 24, and may operate in response to a control signal from the microcomputer 150.

The IR communication controller 140 may be implemented as a switch, and may be implemented as an FET, for example.

The switch 140 may be turned on or off in response to a control signal from the microcomputer 150. For example, the switch 140 may be turned off when receiving a low control signal, and may be turned on when receiving a high control signal.

The microcomputer 150 may output a control signal for communication control over the charger 20, and may diagnose whether at least one of the charge cable connector 110 or the IR communication unit 24 of the charger 20 has failed, based on a voltage value detected by the detection unit 130. In this case, the microcomputer 150 may include a lookup table in which reference voltage values for “Normal”, “Short”, and “Open” with respect to each of the first pin 112 and second pin 114 of the charge cable connector 110 and the IR communication unit 24 have been stored, and may diagnose whether at least one of the charge cable connector 110 or the IR communication unit 24 of the charger 20 has failed, by comparing a voltage value, detected by the detection unit 130, with a reference voltage value stored in the lookup table.

For example, as shown in Table 1 below, the lookup table may store reference voltage values for “Battery Short”, “Ground Short”, and “Open” according to a switch control signal (FET control signal) with respect to the first pin (CN1) 112 and second pin (CN2) 114 of the charge cable connector 110.

TABLE 1

| Failure | FET control | | | |
|---|---|---|---|---|
| situation | signal | CN1 | CN2 | Unit |
| VB short | FET = OFF | Power output impossible | 5 | V |
| | FET = ON | Output power | 5 | V |
| GND short | FET = OFF | semiconductor error flag | 0.43 | V |
| | FET = ON | | 0.43 | V |
| Open | FET = OFF | 3.33 | 3.33 | V |
| | FET = ON | 0.43 | 0.43 | V |

Furthermore, as shown in Table 2, the lookup table may store reference voltage values for “Normal”, “Short” and “Open” according to a switch control signal with respect to the IR communication unit 24. In this case, the IR communication unit 24 may mean an IR communication transmitter.

TABLE 2

| IR communication | | | | |
|---|---|---|---|---|
| transmitter | Normal | SHORT | OPEN | Unit |
| FET = OFF | 4.60 | 4.78 | 3.33 | V |
| FET = ON | 4.03 | 4.78 | 0.43 | V |

The microcomputer 150 may determine whether at least one of the charge cable connector 110 or the IR communication unit 24 of the charger 20 is normal when fuel charging for the fuel cell vehicle 10 is necessary, and may determine that the fuel charging is possible when the charge cable connector 110 and the IR communication unit 24 of the charger 20 are normal.

Specifically, when a voltage value of the power source is not detected before the charge cable connector 110 is connected to the charger 20, the microcomputer 150 may diagnose that the first pin 112 of the charge cable connector 110 has been shorted. When a voltage value of the power source is detected, the microcomputer 150 may turn off the switch 140 by transmitting a low control signal to the switch 140, may compare a voltage value, detected by the detection unit 130, with a reference voltage value stored in the lookup table, and may diagnose the second pin 114 of the charge cable connector 110 as at least one of “Normal”, “Battery Short” or “Ground Short” based on a result of the comparison.

If the first pin 112 and second pin 114 of the charge cable connector 110 are normal and the charge cable connector 110 is connected to the charger 20, the microcomputer 150 may turn off the switch 140 by transmitting a low control signal to the switch 140, may compare a voltage value, detected by the detection unit 130, with a reference voltage value stored in the lookup table, and may diagnose the IR communication unit 24 as at least one of “Normal”, “Short”, or “Open” based on a result of the comparison.

If all of the first pin 112 and second pin 114 of the charge cable connector 110 and the IR communication unit 24 of the charger 20 are normal, the microcomputer 150 may determine that fuel charging for the fuel cell vehicle 10 is possible.

Furthermore, the microcomputer 150 may diagnose whether the IR communication unit 24 has failed during fuel charging for the fuel cell vehicle 10. In this case, the microcomputer 150 may turn off or on the switch 140 by transmitting a low control signal or a high control signal to the switch 140, may compare a voltage value, detected by the detection unit 130, with a reference voltage value stored in the lookup table, and may diagnose the IR communication unit 24 as at least one of “Normal”, “Short”, or “Open” based on a result of the comparison.

The fuel cell charging control apparatus 100 constructed as above may diagnose whether the charger 20 or the IR communication unit 24 is “Open” or “Short”. Furthermore, the fuel cell charging control apparatus 100 may diagnose whether the charge cable connector 110 for IR communication is “Open” or “Short”. Furthermore, the fuel cell charging control apparatus 100 may diagnose whether the IR communication unit 24 and the charge cable connector 110 have failed, by using the two pins of the first pin 112 for power supply and the second pin 114 for communication control without additionally allocating a separate connector pin in order to diagnose whether the IR communication unit 24 and the charge cable connector 110 have failed. Furthermore, the fuel cell charging control apparatus 100 can secure the safety of a driver by determining whether the charger 20 has failed prior to the start of hydrogen fuel charging and during hydrogen fuel charging.

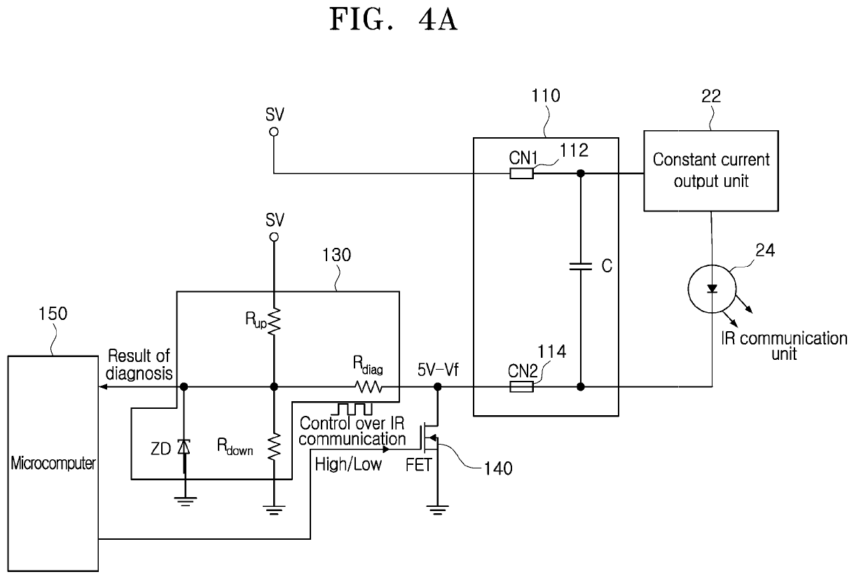

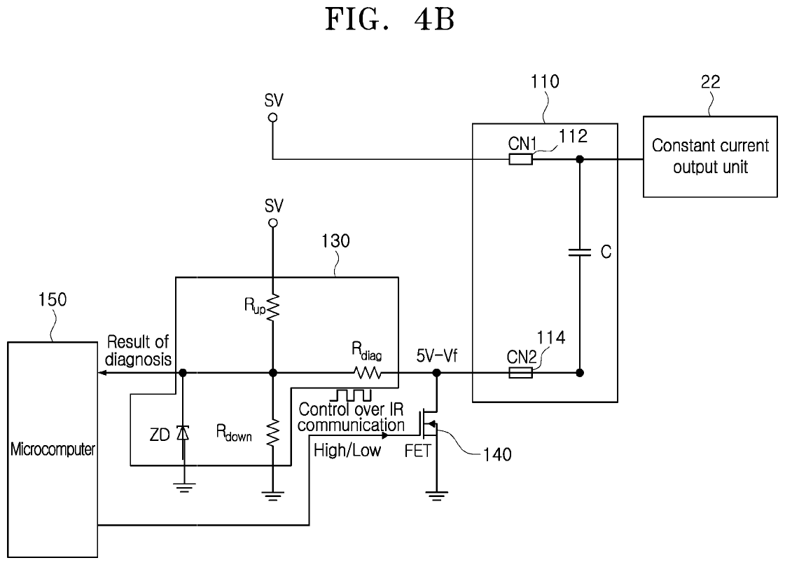

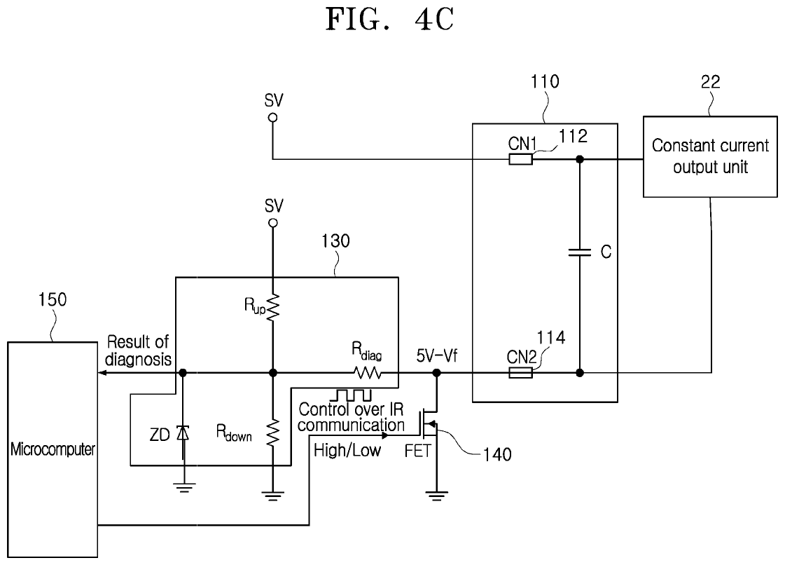

FIGS. 4A-4C are exemplary diagrams for describing a method of diagnosing a failure of the IR communication unit 24 of the charger according to an embodiment of the present disclosure.

As shown in FIG. 4A, when the IR communication unit 24 is normal, the detection unit 130 may calculate, as a diagnosis result, a voltage value in which 5V, that is, the power source, and a 5 V-Vf voltage source according to IR communication control are overlapped. In this case, Vf may mean a change in voltage according to a change in current that flows into the IR communication unit 24 due to internal resistance R_{ds} of the FET. The internal resistance of the FET may vary from several mΩ to MΩ in response to the turn-on/off of the FET, and a current If flowing into the IR communication unit 24 may vary in response to a change in the internal resistance. For example, If may be several uA to a maximum CCR output current (35 mA).

When the IR communication unit 24 is normal, the detection unit 130 may output a voltage value, such as Equation 1 below, as a diagnosis result.

$$Result of diagnosis = \frac{( \frac{{R}_{diag} \cdot {R}_{down}}{{R}_{diag} + {R}_{down}} )}{( \frac{{R}_{diag} \cdot {R}_{down}}{{R}_{diag} + {R}_{down}} ) + {R}_{up}} \cdot 5 V + \frac{( \frac{{R}_{up} \cdot {R}_{down}}{{R}_{up} + {R}_{down}} )}{( \frac{{R}_{up} \cdot {R}_{down}}{{R}_{up} + {R}_{down}} ) + {R}_{diag}} \cdot ( 5 V - {V}_{f} ) \qquad [ Equation 1 ]$$

In Equation 1, Rᵤₚ may mean first resistance, R_{down} may mean second resistance, and R_{diag} may mean third resistance.

A case where the IR communication unit 24 is opened may be the same as the case of FIG. 4B. In this case, the detection unit 130 may output a voltage value, such as Equation 2 below, as a diagnosis result.

$$Result of diagnosis\_failure mode\_OPEN = ( \frac{( \frac{{R}_{down} \cdot ( {R}_{diag} + {R}_{ds\_FET} )}{{R}_{down} + {R}_{diag} + {R}_{ds\_FET}} )}{( \frac{{R}_{down} \cdot ( {R}_{diag} + {R}_{ds\_FET} )}{{R}_{down} + {R}_{diag} + {R}_{ds\_FET}} ) + {R}_{up}} ) \cdot 5 V \qquad [ Equation 2 ]$$

A case where the IR communication unit 24 has been shorted may be the same as that of FIG. 4C. In this case, the detection unit 130 may output a voltage value, such as Equation 3 below, as a diagnosis result.

$$Result of diagnosis\_failure mode\_SHORT = ( \frac{( \frac{{R}_{diag} \cdot {R}_{down}}{{R}_{diag} + {R}_{down}} )}{( \frac{{R}_{diag} \cdot {R}_{down}}{{R}_{diag} + {R}_{down}} ) + {R}_{up}} + \frac{( \frac{{R}_{up} \cdot {R}_{down}}{{R}_{up} + {R}_{down}} )}{( \frac{{R}_{up} \cdot {R}_{down}}{{R}_{up} + {R}_{down}} ) + {R}_{diag}} ) \cdot 5 V \qquad [ Equation 3 ]$$

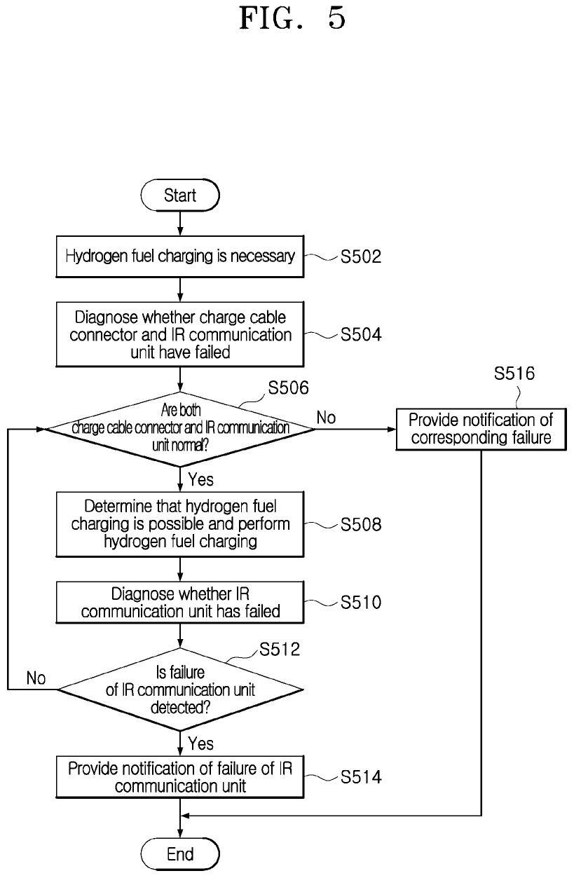

FIG. 5 is a flowchart for describing a method of diagnosing a charger of a fuel cell vehicle according to an embodiment of the present disclosure.

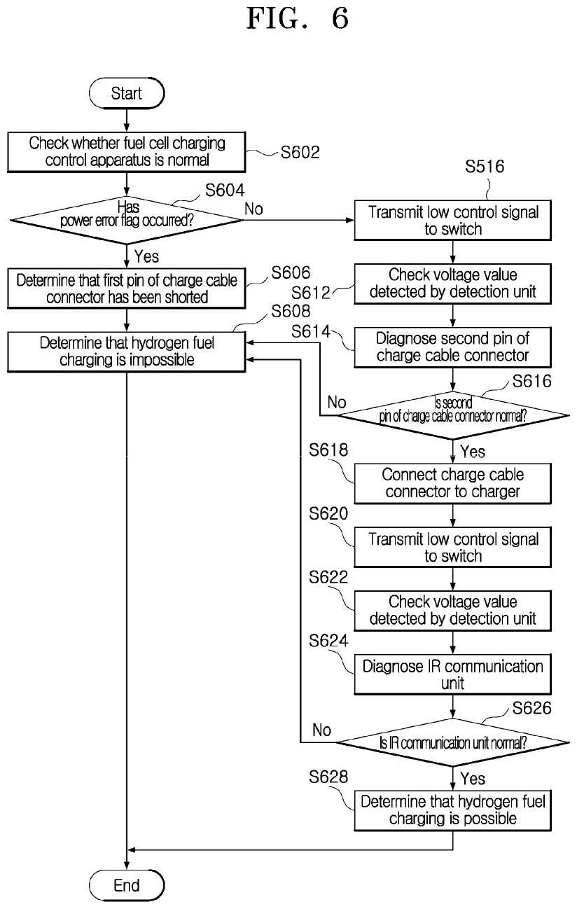

Referring to FIG. 5, if hydrogen fuel charging for the fuel cell vehicle 10 is necessary (S502), the microcomputer 150 diagnoses whether the charge cable connector 110 and the IR communication unit 24 of the charger 20 have failed, before connecting the charge cable connector 110 to the charger 20 (S504). Reference is made to FIG. 6 for a detailed description of a method of diagnosing, by the microcomputer 150, whether the charge cable connector 110 and the IR communication unit 24 of the charger 20 have failed.

When the diagnosis result in step S504 indicates that both the charge cable connector 110 and the IR communication unit 24 of the charger 20 are normal (S506), the microcomputer 150 determines that hydrogen fuel charging for the fuel cell vehicle 10 is possible and performs hydrogen fuel charging (S508).

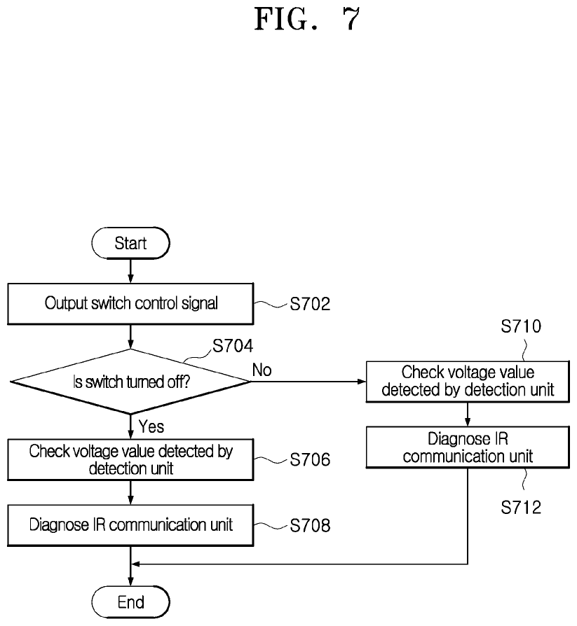

When the hydrogen fuel charging is performed, the microcomputer 150 diagnoses whether the IR communication unit 24 has failed (S510). Reference is made to FIG. 7 for a detailed description of a method of diagnosing, by the microcomputer 150, whether the IR communication unit 24 has failed.

When the diagnosis result in step S510 indicates that a failure of the IR communication unit 24 is detected (S512), the microcomputer 150 provides notification of the failure of the IR communication unit 24 (S514). In this case, the microcomputer 150 may provide notification of the failure of the IR communication unit 24 by using a display unit, an audio unit, etc.

When the diagnosis result in step S504 indicates that either of the charge cable connector 110 and the IR communication unit 24 of the charger 20 is not normal, the microcomputer 150 provides notification of a corresponding failure (S516).

FIG. 6 is a flowchart for describing a method of determining whether hydrogen fuel charging for the fuel cell vehicle 10 may be performed according to an embodiment of the present disclosure.

Referring to FIG. 6, the microcomputer 150 checks whether the fuel cell charging control apparatus 100 is normal (S602). In this case, the microcomputer 150 may determine whether the fuel cell charging control apparatus 100 is normal based on whether a voltage value of the pull-up source is detected.

When the check result in step S602 indicates that a power error flag occurs (S604), the microcomputer 150 determines that the first pin 112 of the charge cable connector 110 has been shorted (S606), and determines that hydrogen fuel charging for the fuel cell vehicle 10 is impossible (S608).

When the check result in step S602 indicates that a power error flag does not occur, the microcomputer 150 determines that the first pin 112 of the charge cable connector 110 is normal and transmits a low control signal to the switch 140 (S610). The switch 140 that has received the low control signal may be turned off.

When step S610 is performed, the microcomputer 150 checks a voltage value detected by the detection unit 130 (S612), and diagnoses the second pin 114 of the charge cable connector 110 based on the checked voltage value (S614). At this time, the microcomputer 150 may compare the voltage value, detected by the detection unit 130, with a reference voltage value stored in the lookup table, and may diagnose at least one of “Normal”, “Short”, or “Open” for the second pin 114 of the charge cable connector 110 based on a result of the comparison.

For example, if reference voltage values have been stored as shown in Table 1, the microcomputer 150 may diagnose whether the second pin 114 has failed. In this case, when the voltage value detected by the detection unit 130 is 5 V, the microcomputer 150 may diagnose the second pin 114 of the charge cable connector 110 as “Battery Short.” Furthermore, when the voltage value detected by the detection unit 130 is 0.43 V, the microcomputer 150 may diagnose the second pin 114 of the charge cable connector 110 as “Ground Short”. Furthermore, when the voltage value detected by the detection unit 130 is 3.33 V, the microcomputer 150 may determine that the second pin 114 of the charge cable connector 110 is normal.

When the diagnosis result in step S614 indicates that the second pin 114 of the charge cable connector 110 is normal (S616) and it is detected that the charge cable connection 110 is connected to the charger 20 (S618), the microcomputer 150 transmits a low control signal to the switch 140 (S620), and checks a voltage value detected by the detection unit 130 (S622).

The microcomputer 150 diagnoses the IR communication unit 24 based on the voltage value checked in step S622 (S624). At this time, the microcomputer 150 may compare the voltage value, detected by the detection unit 130, with a reference voltage value stored in the lookup table, and may diagnose the IR communication unit 24 as at least one of “Normal”, “Short”, or “Open” based on a result of the comparison.

For example, if reference voltage values have been stored as shown in Table 2, the microcomputer 150 may diagnose whether the IR communication unit 24 has failed. In this case, when the voltage value detected by the detection unit 130 is 4.78 V, the microcomputer 150 may diagnose the IR communication unit 24 as “Short.” Furthermore, when the voltage value detected by the detection unit 130 is 3.33 V, the microcomputer 150 may diagnose the IR communication unit 24 as “Open.” Furthermore, when the voltage value detected by the detection unit 130 is 4.6 V, the microcomputer 150 may determine that the IR communication unit 24 is normal.

When the diagnosis result in step S624 indicates that the IR communication unit 24 is normal (S626), the microcomputer 150 determines that hydrogen fuel charging for the fuel cell vehicle 10 is possible (S628).

When the diagnosis result in step S624 indicates that the IR communication unit 24 is not normal (S626), the microcomputer 150 determines that hydrogen fuel charging for the fuel cell vehicle 10 is impossible.

FIG. 7 is a flowchart for describing a method of diagnosing whether the IR communication unit has failed during fuel charging for a vehicle according to an embodiment of the present disclosure.

Referring to FIG. 7, while the vehicle 10 is charged with fuel, the microcomputer 150 transmits a switch control signal to the switch 140 (S702). When the switch 140 is turned off (S704), the microcomputer 150 checks a voltage value detected by the detection unit 130 (S706).

When step S706 is performed, the microcomputer 150 diagnoses the IR communication unit 24 based on the voltage value checked in step S706 (S708). At this time, the microcomputer 150 may compare the voltage value, detected by the detection unit 130, with a reference voltage value stored in the lookup table, and may diagnose the IR communication unit 24 as at least one of “Normal”, “Short”, or “Open” based on a result of the comparison.

For example, if reference voltage values have been stored as shown in Table 2, the microcomputer 150 may diagnose whether the IR communication unit 24 has failed. In this case, when the voltage value detected by the detection unit 130 is 4.78 V, the microcomputer 150 may diagnose the IR communication unit 24 as “Short”. Furthermore, when the voltage value detected by the detection unit 130 is 3.33 V, the microcomputer 150 may diagnose the IR communication unit 24 as “Open”. Furthermore, when the voltage value detected by the detection unit 130 is 4.6 V, the microcomputer 150 may determine that the IR communication unit 24 is normal.

When the microcomputer 150 transmits a high control signal that turns on the switch 140, in step S702, the microcomputer 150 checks a voltage value detected by the detection unit 130 (S710), and diagnoses the IR communication unit 24 based on the checked voltage value (S712). At this time, the microcomputer 150 may compare the voltage value of the voltage distribution circuit of the detection unit 130 with a reference voltage value stored in the lookup table, and may diagnose the IR communication unit 24 as at least one of “Normal”, “Short”, or “Open” based on a result of the comparison.

For example, if reference voltage values have been stored as shown in Table 2, the microcomputer 150 may diagnose whether the IR communication unit 24 has failed. In this case, when the voltage value detected by the detection unit 130 is 4.78 V, the microcomputer 150 may diagnose the IR communication unit 24 as “Short.” Furthermore, when the voltage value detected by the detection unit 130 is 0.43 V, the microcomputer 150 may diagnose the IR communication unit 24 as “Open.” Furthermore, when the voltage value detected by the detection unit 130 is 4.03 V, the microcomputer 150 may determine that the IR communication unit 24 is normal.

As described above, the system and method for diagnosing a charger for a fuel cell vehicle according to embodiments of the present disclosure can secure the safety of a driver of a fuel cell vehicle by diagnosing the failure of the charge cable connector and the IR communication unit of the charger, which may occur during actual charging as well as prior to fuel charging for the fuel cell vehicle.

The system and method for diagnosing a charger for a fuel cell vehicle according to embodiments of the present disclosure can diagnose whether the IR communication unit and the charge cable connector have failed, by using a total of two pins of the first pin for power supply and the second pin for communication control, without additionally allocating a separate connector pin in order to diagnose whether the IR communication unit and the charge cable connector have failed.

The system and method for diagnosing a charger for a fuel cell vehicle according to embodiments of the present disclosure can secure the safety of a driver by determining whether the IR communication unit of the charger has failed, prior to the start of hydrogen fuel charging and during hydrogen fuel charging.

Although the present disclosure has been described with reference to the embodiments illustrated in the drawings, the embodiments are merely illustrative, and those skilled in the art will understand that various modifications and other equivalent embodiments are possible from the embodiments.

Accordingly, the true technical range of protection of the present disclosure should be determined by the technical spirit of the following claims.

What is claimed is:

1. A system for diagnosing a charger for a fuel cell vehicle, comprising:
a charge cable connector comprising a first pin for power supply and a second pin for communication control and configured to be connected to the charger of a fuel charging station;
a detection unit configured to detect a voltage value based on whether the charge cable connector is connected to the charger;
a microcomputer configured to output a control signal for communication control over the charger and diagnose whether at least one of the charge cable connector or an infrared ray (IR) communication unit of the charger has failed, based on the detected voltage value; and
a switch configured to be turned on or off in response to the control signal.

2. The system of claim 1, wherein the detection unit comprises:
a first resistor having one side connected in series to a power source;
a second resistor having one side connected in series to a ground; and
a third resistor having one side connected in series to the second pin,
wherein at least one of the first resistor, the second resistor, or the third resistor forms a voltage distribution circuit.

3. The system of claim 2, wherein the detection unit further comprises a Zener diode having one side connected in parallel to the microcomputer and the other side connected to the ground, and configured to protect the microcomputer upon battery open in at least one of the first pin or the second pin.

4. The system of claim 1, wherein the microcomputer is configured to:
diagnose whether at least one of the charge cable connector or the IR communication unit has failed when fuel charging for the fuel cell vehicle is necessary, and
determine that fuel charging is possible when the charge cable connector and the IR communication unit are normal.

5. The system of claim 4, wherein the microcomputer is configured to:
when a voltage value of a power source is not detected before the charge cable connector is connected to the charger, diagnose the first pin as short, and
when the voltage value of the power source is detected, turn off the switch by transmitting a low control signal to the switch, compare a voltage value, detected by the detection unit, with a reference voltage value stored in a lookup table, and diagnose the second pin as at least one of normal, battery short or ground short based on a result of the comparison.

6. The system of claim 5, wherein when the first pin and second pin of the charge cable connector are normal and the charge cable connector is connected to the charger, the microcomputer is configured to:
turn off the switch by transmitting a low control signal to the switch,
compare a voltage value, detected by the detection unit, with a reference voltage value stored in the lookup table, and
diagnose the IR communication unit as at least one of normal, short, or open based on a result of the comparison.

7. The system of claim 1, wherein the microcomputer is configured to diagnose whether the IR communication unit has failed upon fuel charging for the fuel cell vehicle.

8. The system of claim 7, wherein upon fuel charging for the fuel cell vehicle, the microcomputer is configured to:
turn off or on the switch by transmitting a low control signal or a high control signal to the switch,
compare a voltage value, detected by the detection unit, with a reference voltage value stored in a lookup table, and
diagnose the IR communication unit as at least one of normal, short, or open based on a result of the comparison.

9. A method of diagnosing a charger for a fuel cell vehicle, comprising:
diagnosing, by a microcomputer, whether at least one of a charge cable connector or an infrared ray (IR) communication unit of the charger has failed when fuel charging for a fuel cell vehicle is necessary;
determining, by the microcomputer, that fuel charging for the fuel cell vehicle is possible when both the charge cable connector and the IR communication unit are normal; and
diagnosing, by the microcomputer, whether the IR communication unit has failed upon fuel charging for the fuel cell vehicle.

10. The method of claim 9, wherein in diagnosing whether the at least one of the charge cable connector or the IR communication unit of the charger has failed, the microcomputer is configured to:
when a voltage value of a power source is not detected before the charge cable connector is connected to the charger, diagnose the first pin of the charge cable connector as short, and
when the voltage value of the power source is detected, turn off the switch by transmitting a low control signal to the switch, compare a voltage value, detected by a detection unit, with a reference voltage value stored in a lookup table, and diagnose the second pin of the charge cable connector as at least one of normal, battery short or ground short based on a result of the comparison.

11. The method of claim 10, wherein in diagnosing whether the at least one of the charge cable connector or the IR communication unit of the charger has failed, when the first pin and second pin are normal and the charge cable connector is connected to the charger, the microcomputer is configured to:
turn off the switch by transmitting a low control signal to the switch,
compare a voltage value, detected by the detection unit, with a reference voltage value stored in the lookup table, and
diagnose the IR communication unit as at least one of normal, short, or open based on a result of the comparison.

12. The method of claim 9, wherein in diagnosing whether the IR communication unit has failed, the microcomputer is configured to:
turn off or on the switch by transmitting a low control signal or a high control signal to the switch,
compare a voltage value, detected by a detection unit, with a reference voltage value stored in a lookup table, and
diagnose the IR communication unit as at least one of normal, short, or open based on a result of the comparison.
